(19) United States
(12) Patent Application Publication
(10) Pub. No.: US 2021/0398972 A1
(43) Pub. Date: Dec. 23, 2021

(54) INTEGRATING A GATE-ALL-AROUND (GAA) TRANSISTOR WITH A SILICON GERMANIUM (SiGe) HETEROJUNCTION BIPOLAR TRANSISTOR (HBT)

(71) Applicant: QUALCOMM Incorporated, San Diego, CA (US)

(72) Inventors: Bin YANG, San Diego, CA (US); Haining YANG, San Diego, CA (US); Xia LI, San Diego, CA (US); Kwanyong LIM, San Diego, CA (US)

(21) Appl. No.: 16/908,126

(22) Filed: Jun. 22, 2020

(51) Int. Cl. H01L 27/06; H01L 29/423; H01L 29/737; H01L 29/786; H01L 21/8249; H01L 29/10; H01L 29/08

(52) U.S. Cl. CPC H01L 27/0623; H01L 29/42392; H01L 29/7378; H01L 29/0821; H01L 21/8249; H01L 29/1004; H01L 29/78696

(57) ABSTRACT

Certain aspects of the present disclosure generally relate to a semiconductor device with a heterojunction bipolar transistor (HBT) integrated with a gate-all-around (GAA) transistor. One example semiconductor device generally includes a first substrate, a second substrate adjacent to the first substrate, a GAA transistor disposed above the first substrate, and a HBT disposed above the second substrate. Other aspects of the present disclosure generally relate to a method for fabricating a semiconductor device. An exemplary fabrication method generally comprises forming a GAA transistor disposed above a first substrate and forming a HBT disposed above a second substrate, wherein the second substrate is adjacent to the first substrate.

### BACKGROUND

### Field of the Disclosure

Certain aspects of the present disclosure generally relate to electronic components and, more particularly, to a semiconductor device comprising a gate-all-around (GAA) transistor and a heterojunction bipolar transistor (HBT).

### Description of Related Art

A continued emphasis in semiconductor technology is to create improved performance semiconductor devices at competitive prices and/or with smaller sizes. This emphasis over the years has resulted in extreme miniaturization of semiconductor devices, made possible by continued advances in semiconductor processes and materials in combination with new and sophisticated device designs. Large numbers of transistors are employed in integrated circuits (ICs) in many electronic devices. For example, components such as central processing units (CPUs), graphics processing units (GPUs), and memory systems each employ a large quantity of transistors for logic circuits and memory devices.

Gate-all-around (GAA) field-effect transistors (FETs) have enabled a reduction of transistor node sizes to 10 nm, and in some cases 7 nm down to 3 nm. In certain cases, GAA FETs have nanowires, which form the channels, embedded in gate material disposed between the source and drain of the GAA FET. GAA FETs may be designed to have a lower threshold voltage than similar fin field-effect transistor (FinFET) devices, because GAA FETs may have better short channel control, allowing for a reduction in supply voltage that results in a quadratic reduction in power consumption because of voltage scaling.

Heterojunction bipolar transistors (HBTs) have seen implementation in modern ultrafast circuits, including radio-frequency (RF) systems, and in applications with high power efficiency specifications, such as RF power amplifiers in cellular phones. In contrast with bipolar junction transistors (BJTs), HBTs use different semiconductor materials for the emitter-base junction and the base-collector junction, creating a heterojunction. The heterojunction allows a high doping density to be used in the base, reducing the base resistance while maintaining gain.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include improved integration of a gate-all-around (GAA) transistor with a heterojunction bipolar transistor (HBT).

Certain aspects of the present disclosure provide a semiconductor device and methods for fabrication of the semiconductor device. The semiconductor device generally includes a HBT integrated with a GAA transistor.

One example semiconductor device generally includes a first substrate, a second substrate adjacent to the first substrate, a GAA transistor disposed above the first substrate, and a HBT disposed above the second substrate.

Other aspects of the present disclosure generally relate to a method for fabricating a semiconductor device. An exemplary fabrication method generally includes forming a GAA transistor above a first substrate and forming a HBT above a second substrate, wherein the second substrate is adjacent to the first substrate.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 illustrates a cross-sectional view of an example semiconductor device, in accordance with certain aspects of the present disclosure.

FIGS. 2A-2W illustrate example operations for fabricating the semiconductor device of FIG. 1, in accordance with certain aspects of the present disclosure.

FIG. 3 is a flow diagram of example operations for fabricating a semiconductor device, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure relate to integrating gate-all-around (GAA) complementary metal-oxide-semiconductor (CMOS) transistors with a silicon germanium (SiGe) heterojunction bipolar transistor (HBT). Currently, effectively integrating CMOS (e.g., GAA CMOS) with silicon germanium (SiGe) HBT is challenging. Attempts to integrate bipolar junction transistors (BJTs) or HBTs with various types of fin field-effect transistor (FinFET) CMOS devices have proven generally successful; however, integration of GAA CMOS and SiGe HBT has been difficult to achieve. Certain aspects of the present disclosure are directed to a semiconductor device and a process flow that leverages and integrates GAA CMOS with SiGe HBT on the same chip, in a manner that decreases cost and improves performance as compared to conventional implementations.

Bipolar CMOS (BiCMOS) generally refers to a semiconductor technology that integrates bipolar junction transistors and CMOS transistors. Current BiCMOS implementations of 90 nm CMOS with SiGe BJT are less effective than integration of CMOS with SiGe HBT in terms of noise and speed performance. Integrating CMOS and SiGe HBT effectively integrates CMOS performance (e.g., low power and typically used for digital applications) with the HBT performance (e.g., low noise and high speed), in the same system-on-a-chip (SoC).

Certain aspects of the present disclosure generally relate to a process flow to leverage GAA CMOS epitaxy (EPI) with a SiGe HBT EPI structure. Certain aspects of the present disclosure provide integration of GAA CMOS with SiGe HBT, with few additional process steps or masks as compared to conventional semiconductor fabrication processes.

In certain aspects, GAA CMOS may be integrated with SiGe HBT where the HBT has a SiGe base. The fabrication process for integration of GAA CMOS and SiGe HBT may have process steps shared between formation of the GAA CMOS and the SiGe HBT. In certain aspects, the GAA CMOS may have a p-type SiGe or p-type silicon (Si) EPI structure. Additionally, the GAA CMOS and the HBT may share the same p-type SiGe or p-type Si EPI. In certain aspects, front-end-of-line (FEOL) and back-end-of-line (BEOL) process steps may be shared for fabrication of the GAA CMOS and HBT.

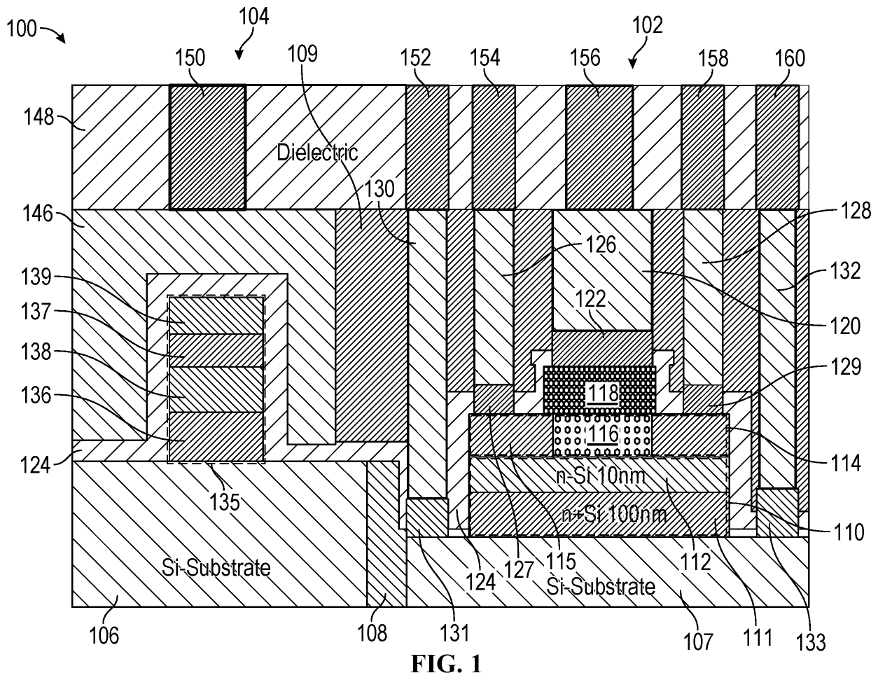

FIG. 1 illustrates an example semiconductor device 100, in accordance with certain aspects of the present disclosure. As shown, the semiconductor device 100 may include an HBT 102 and a GAA transistor 104, which may be disposed, respectively, above substrate 107 and substrate 106. The GAA transistor 104 may be part of a GAA CMOS transistor pair, not shown in FIG. 1. The substrate 106 may be a portion of, for example, a semiconductor wafer such as a silicon wafer. The same may be said of substrate 107. A dielectric region 108 may be disposed between substrate 106 and substrate 107 to separate the GAA transistor 104 and the HBT 102. For instance, the dielectric region 108 may be a shallow trench isolation (STI) region configured to electrically isolate—or at least increase the electrical isolation of—the HBT 102 disposed above the substrate 107 from other electrical devices including the GAA transistor 104 disposed above the substrate 106.

In certain aspects, the HBT 102 may be disposed adjacent to the GAA transistor 104. The HBT 102 may include a collector region 110, a base region 114, and an emitter layer 118. The collector region 110 may include a sub-collector layer 111 and a collector layer 112. The base region 114 may include a base sub-region 115 and a base sub-region 116 (also referred to as “material regions”). The base sub-region 115 may have a higher doping concentration than the base sub-region 116. The base region 114 may be disposed above the collector region 110. The emitter layer 118 may be disposed above the base region 114. The HBT 102 may further include an emitter contact 120 and an emitter contact metal 122. The emitter contact metal 122 may electronically couple the emitter contact 120 to the emitter layer 118. The HBT 102 may further include a dielectric 124 adjacent to the collector region 110, the base region 114, and the emitter layer 118. The HBT 102 may further include a base contact 126 and a base contact 128, both of which may be composed of tungsten (W), for example. The base contacts 126 and 128 may be electronically coupled to the base region 114 by, respectively, base contact metal 127 and base contact metal 129. The base contact metals 127 and 129 may be composed of platinum (Pt), titanium (Ti), or the like. The HBT 102 may further include a collector contact 130 and a collector contact 132, both of which may be composed of tungsten, for example. The collector contacts 130 and 132 may be electronically coupled to the sub-collector layer 111 by, respectively, collector contact metal 131 and collector contact metal 133. The collector contact metals 131 and 133 may be composed of platinum silicide, titanium silicide, or the like.

The collector region 110 may be composed of a semiconductor material, such as silicon (Si). In certain aspects, the semiconductor material of the collector region 110 may be an n-type or p-type semiconductor material (e.g., via doping). In certain aspects, the sub-collector layer 111 and collector layer 112 may have different heights. For example, the sub-collector layer 111 may have a height ranging from 100 to 200 nm, whereas the collector layer 112 may have a height ranging from 5 to 10 nm. In other aspects, the sub-collector layer 111 and collector layer 112 may have the same height.

The base region 114 may be composed of at least one semiconductor material, such as SiGe or silicon germanium doped with carbon (SiGe:C). In certain aspects, the semiconductor material of the base region 114 may be an n-type or p-type semiconductor material. For example, the semiconductor material of the base sub-region 115 may be composed of p+ type SiGe:C. Furthermore, the height of the base sub-region 115 may be about 10 nm, for example. The base sub-region 116 may be composed of a different material than the base sub-region 115. For example, the base sub-region 116 may be composed of SiGe, and the base sub-region 115 may be composed of p+ type SiGe:C.

The emitter layer 118 may be composed of at least one semiconductor material, such as SiGe. In certain aspects, the semiconductor material of the emitter layer 118 may be an n-type or p-type semiconductor material.

The collector region 110, base region 114, and emitter layer 118 may each be adjacent to the dielectric 124, as illustrated. The dielectric 124 may be composed of an oxide, for example. In certain aspects, the HBT 102 and the GAA transistor 104 may include a dielectric 109, as illustrated. The dielectric 109 may electrically insulate the various metal structures of the HBT 102 and the GAA transistor 104 from one another.

In certain aspects, the GAA transistor 104 may include a plurality of layers making up a stack 135. Such layers may include gate layers 136 and 137. The gate layers 136 and 137 may be high-κ metal gate layers. The gate layers 136 and 137 may each include a conductive layer disposed adjacent to at least one dielectric layer. The gate layers 136 and 137 additionally may have a height of about 10 nm, for example.

Other layers of the stack 135 may include channel layers 138 and 139. The channel layer 138 may be disposed between the gate layers 136 and 137. The channel layer 139 may be disposed between the gate layer 137 and a portion of the dielectric 124, as illustrated. The channel layers 138 and 139 may be composed of a semiconductor material, such as Si.

In certain aspects, the stack 135 may be disposed above the substrate 106. The dielectric 124 may be disposed above and adjacent to lateral surfaces of the stack 135, as illustrated. In certain aspects, a gate region 146 may be disposed adjacent to at least one surface of the dielectric 124, as illustrated. In certain aspects, the semiconductor device 100 may include a dielectric 148, which may be smoothed through chemical-mechanical polishing (CMP) to be planarized, as illustrated.

While the examples provided herein are described with respect to the stack 135 comprising channel layers and gate layers to facilitate an understanding, aspects of the present disclosure may also be applied to other suitable GAA structures. For example, the stack structure may be replaced by a gate structure having semiconductor nanowires (e.g., channels) that intersect the gate structure, which may include various work function metals.

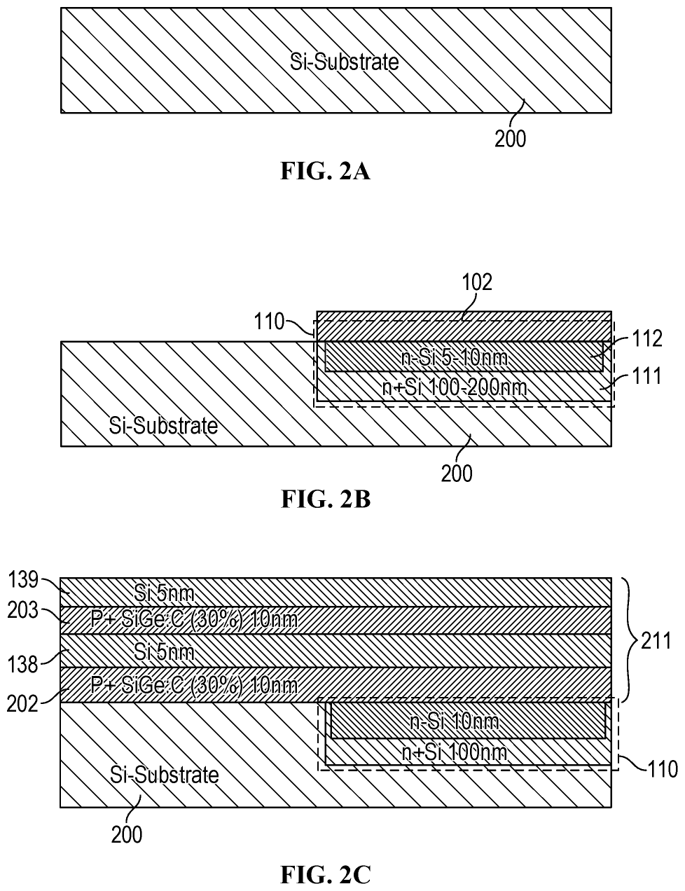

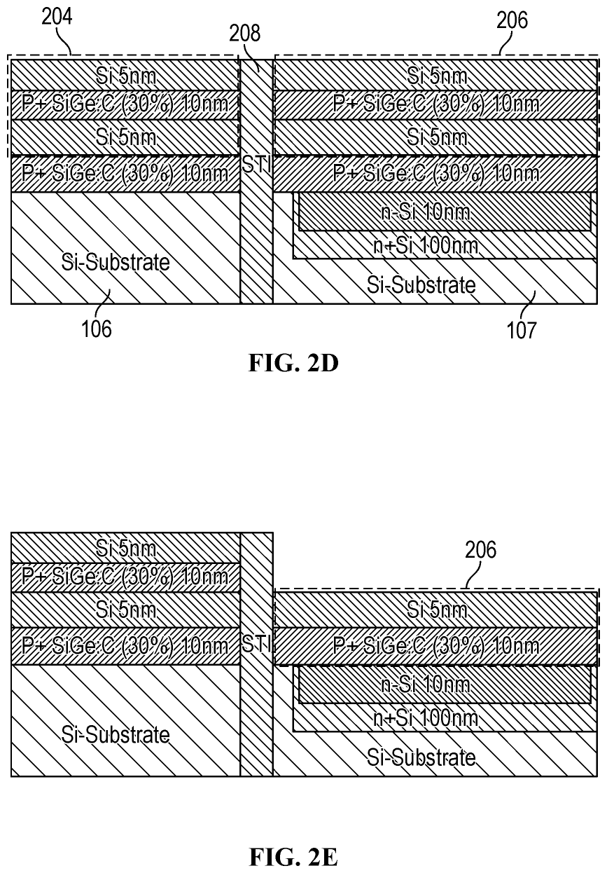

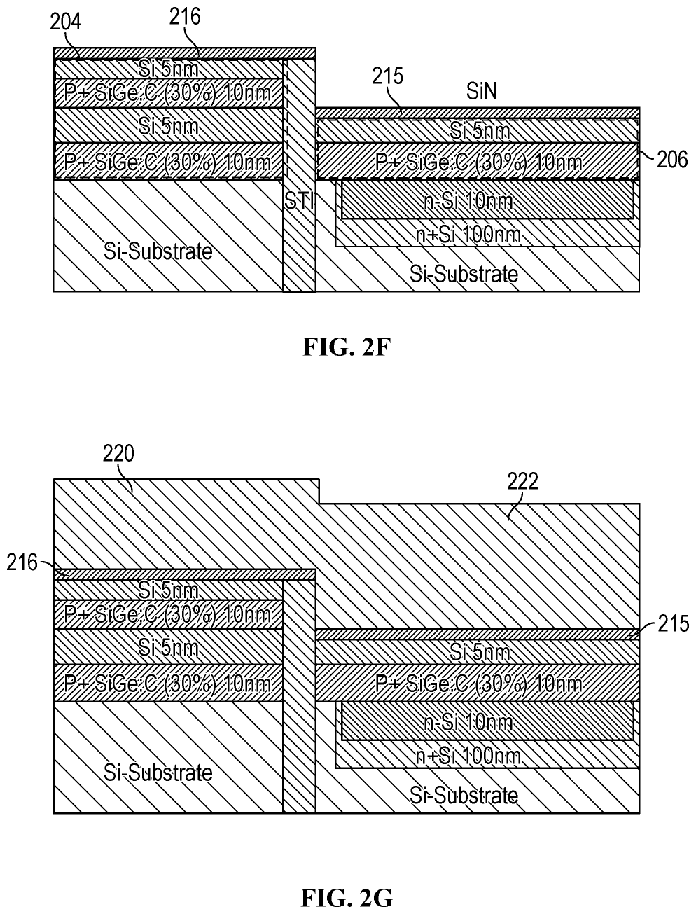

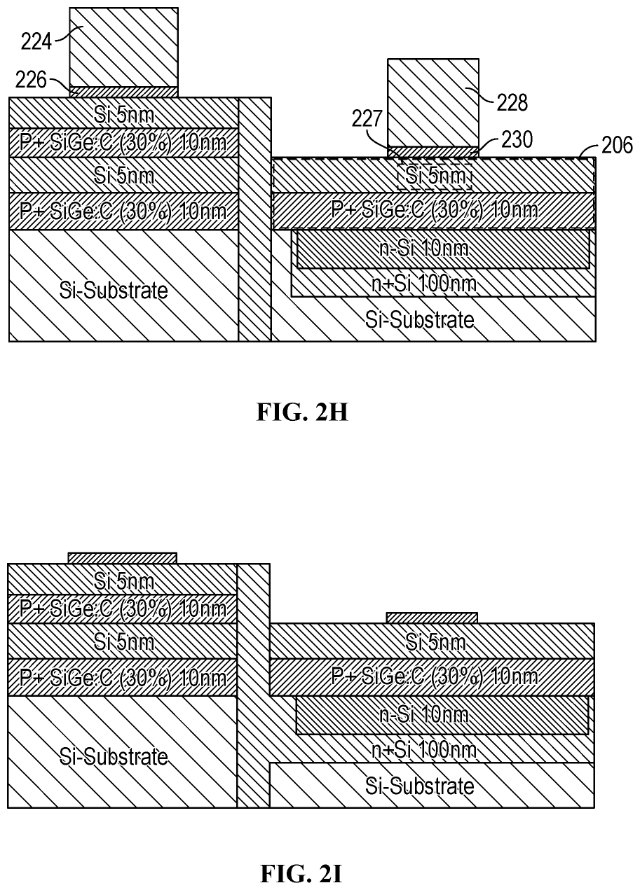

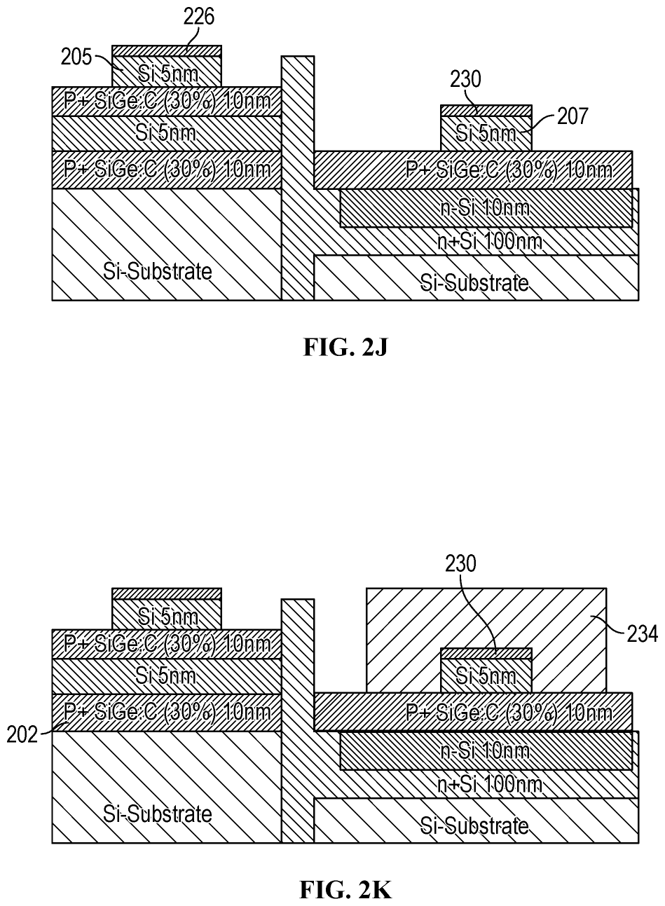

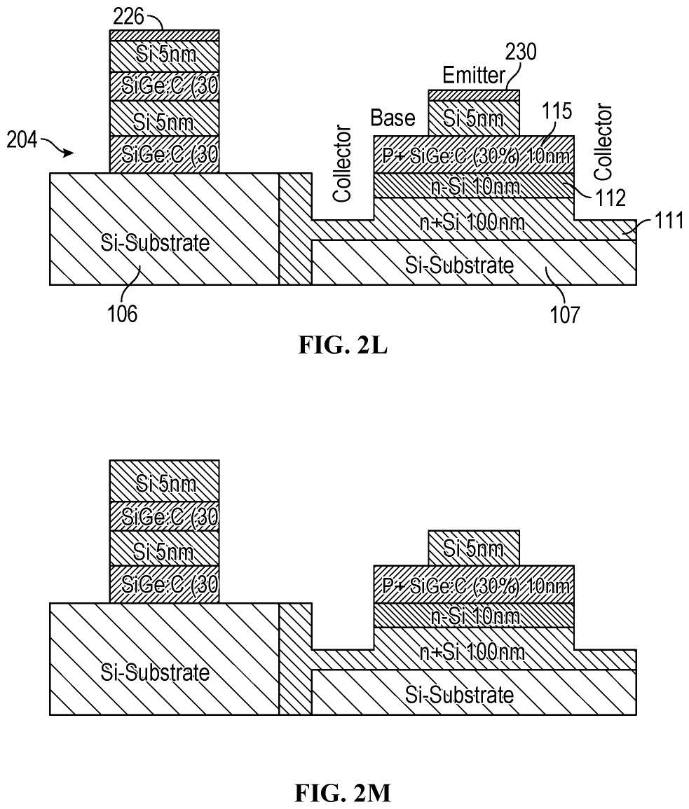

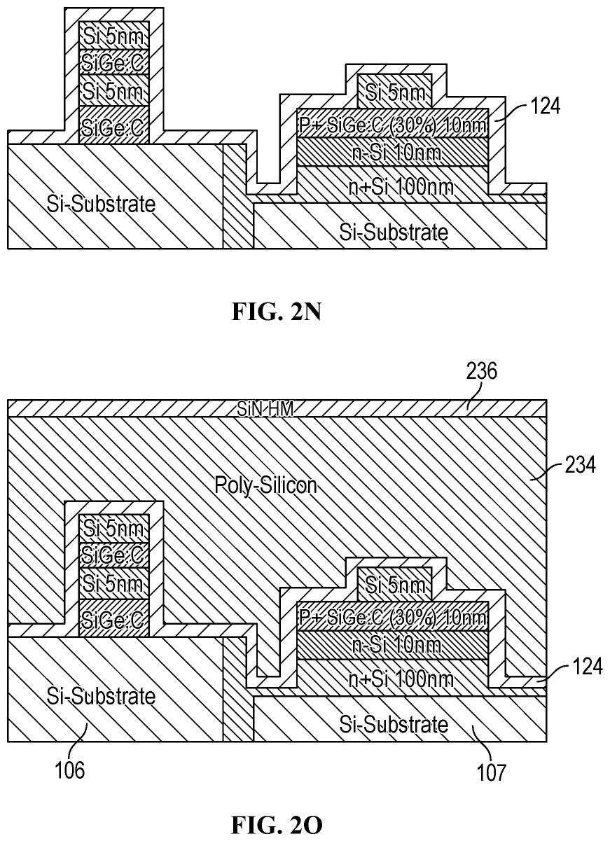

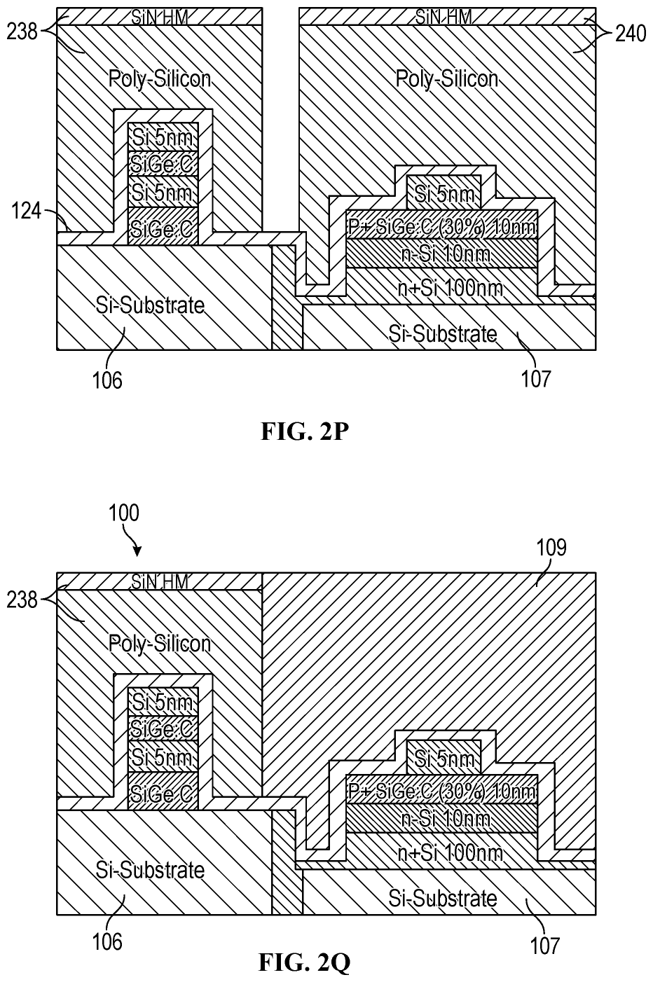

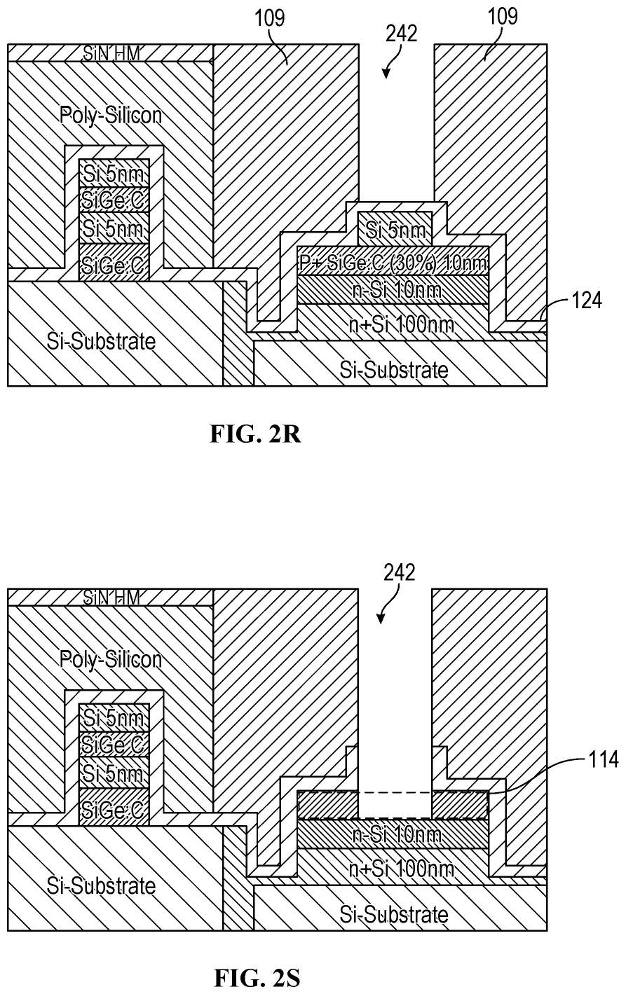

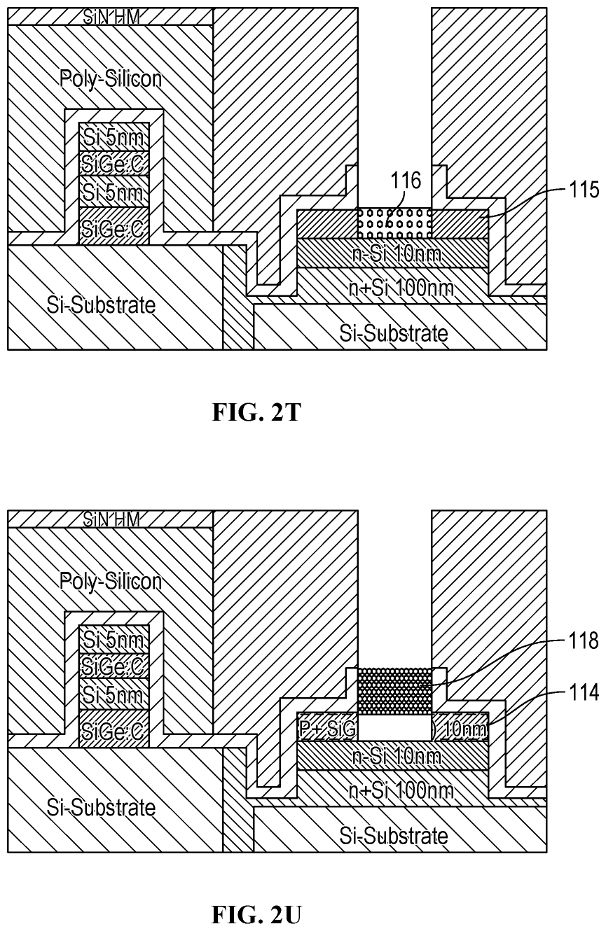

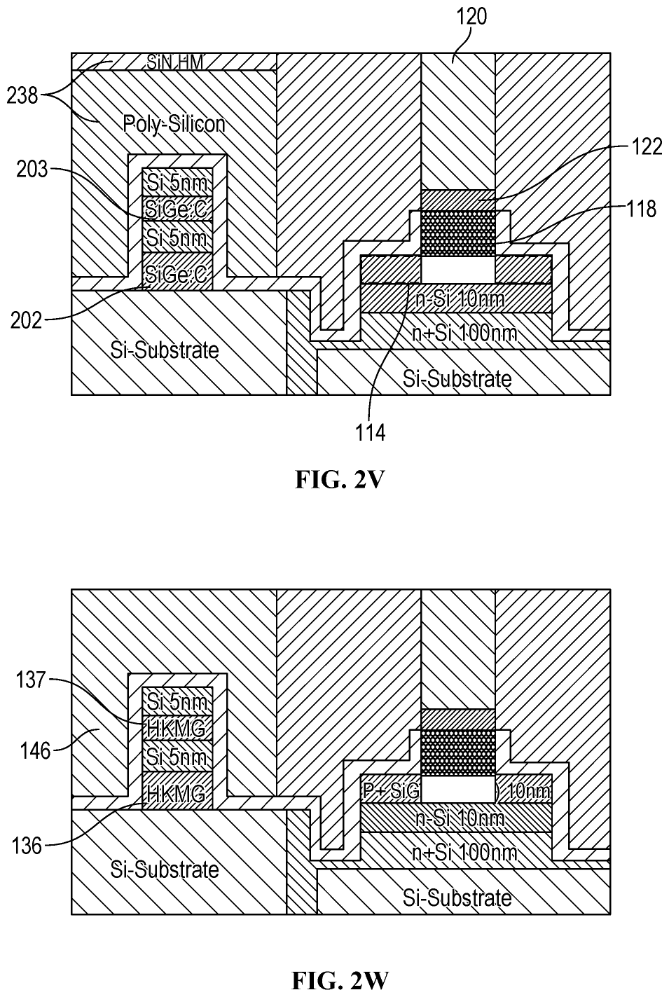

FIGS. 2A-2W illustrate example operations for fabricating the semiconductor device 100, in accordance with certain aspects of the present disclosure. The operations may be performed by a semiconductor fabrication facility, for example. The operations may include various front-end-of-line (FEOL) fabrication processes, when electrical devices are patterned on a substrate (e.g., substrate 106 and substrate 107), and various back-end-of-line (BEOL) fabrication processes, when the electrical devices are electrically interconnected.

FIG. 2A illustrates a cross-sectional view of a substrate 200 that may be later divided into substrate 106 and substrate 107 as depicted in FIG. 1. The substrate 200 may be composed of Si, as shown in FIG. 2A.

FIG. 2B illustrates the collector region 110 implanted into a region for the HBT 102 of the substrate 200. Si that is n+ doped and Si that is n− doped may be formed (e.g., implanted) in the region for the HBT 102 to form collector layer 112 and sub-collector layer 111, respectively, followed by annealing to activate the dopant.

FIG. 2C illustrates a plurality of layers 211 of alternating semiconductor materials deposited above the substrate 200. There may be two different types of alternating semiconductor materials, such as Si and SiGe:C, formed using EPI growth. In certain aspects, the SiGe:C may be p+ doped. In certain aspects, the plurality of layers 211 may include four layers (channel layers 138, 139 and layers 202, 203), where adjacent layers alternate between different types of semiconductor material (e.g., layer 202 is SiGe:C and channel layer 138 is Si). The plurality of layers 211 may have similar width, as illustrated.

FIG. 2D illustrates a dielectric region 208 formed in an interior portion (e.g., a middle portion) of the semiconductor device 100. The dielectric region 208 may correspond to the dielectric region 108 (e.g., STI) between the GAA transistor 104 and HBT 102. Thus, a first layer stack 204 and a second layer stack 206 are formed which are separated by the dielectric region 108.

As shown in FIG. 2E, at least one layer of the second layer stack 206 may be selectively removed (e.g., using lithographical etching), such that the first layer stack 204 has more layers. In certain aspects, the first layer stack 204 may be lithographically covered, and the second layer stack 206 may be exposed. The top Si layer of the second layer stack 206 may then be removed. In certain aspects, the p+ SiGe:C layer of second layer stack 206 may be selectively removed, stopping on the underlying Si layer of the second layer stack 206, as illustrated.

As illustrated in FIG. 2F, a first hard mask 216 may be deposited above the first layer stack 204, and a second hard mask 215 may be deposited above the second layer stack 206. For example, the first hard mask 216 and the second hard mask 215 may be composed of silicon nitride (Si₃N₄).

Referring to FIG. 2G, a photoresist coat 220 and a photoresist coat 222 are formed above the hard mask 216 and the hard mask 215, respectively. The photoresist coat 220 and the photoresist coat 222 may be applied using a lithography process.

As depicted in FIG. 211, both the photoresist coat 220 and the hard mask 216 of FIG. 2G may be lithographically etched to each have a smaller width, as shown. The width of the reduced hard mask 226 and the reduced photoresist coat 224 may be similar. Similarly, a reduced photoresist coat 228 and a reduced hard mask 230 of FIG. 211 may be formed. The region 227 may be used to form the emitter layer 118, as described in more detail herein.

As illustrated in FIG. 21, the reduced photoresist coat 224 and the reduced photoresist coat 228 may be removed. Referring to FIG. 2J, the layers 205, 207 may be etched to leave a portion of their original widths. The resulting width of the first layer stack 204 may correspond to that of the first reduced hard mask 226, and the same may be said when comparing the second layer stack 206 and the second reduced hard mask 230. For example, the layer 205 is etched down to the SiGe:C layer for the removed portions not covered by the first reduced hard mask 226, as illustrated. As illustrated in FIG. 2K, the second reduced hard mask 230 may be covered by a dummy gate 234. The dummy gate 234 may be composed of a photoresistant material.

As illustrated in FIG. 2L the first layer stack 204 may be selectively etched down to the substrate 106. Moreover, the base sub-region 115 and the collector layer 112 may be etched. As illustrated in FIG. 2M, the first reduced hard mask 226 and the second reduced hard mask 230 may be removed. As illustrated in FIG. 2N, dielectric 124 may be deposited along the top of the semiconductor device. The dielectric 124 may be of high quality oxide. Furthermore, the deposition method of the dielectric 124 may be plasma enhanced (PE) atomic layer deposition (ALD).

As illustrated in FIG. 2O, a dummy gate 234 may be deposited above the dielectric 124. The dummy gate 234 may be composed of poly-silicon. At least one side of the dummy gate 234 may undergo CMP polishing to planarize the dummy gate 234. Additionally, an upper hard mask 236 may be deposited above the dummy gate 234. The upper hard mask may be silicon nitride (Si₃N₄).

As illustrated in FIG. 2P, the dummy gate 234 and the upper hard mask 236 may both be selectively etched to create a first dummy gate and hardmask region 238 and a second dummy gate and hardmask region 240. The first dummy gate and hardmask region 238 may have a width less than that of the substrate 106 while still being adjacent to a portion of the dielectric 124. The second dummy gate and hardmask region 240 may have a width similar to that of the substrate 107. As illustrated in FIG. 2Q, the second dummy gate and hardmask region 240 may be removed, and the resulting space may be filled with the dielectric 109. Additionally, the top of the dielectric 109 may undergo CMP planarization.

As illustrated in FIG. 2R, the dielectric 109 may be selectively etched to form a contact window 242. The contact window 242 may be an emitter contact window and may extend from the top of the dielectric 109 to the dielectric 124. As illustrated in FIG. 2S, the contact window 242 may be extended through the base region 114.

Referring to FIG. 2T, the base sub-region 116 may be epitaxially grown. The base sub-region 116 may be located adjacent to the base sub-region 115. As illustrated in FIG. 2U, the emitter layer 118 may be epitaxially grown. The emitter layer 118 may be composed of N+Si and N+ SiGe composite layers. The emitter layer may be disposed above the base region 114.

Referring to FIG. 2V, the emitter contact metal 122 may be deposited above the emitter layer 118 to electrically connect the emitter contact 120 (e.g., tungsten (W)) to the emitter layer 118. In certain aspects, the emitter contact metal 122 may be composed of titanium (Ti). In other aspects, the emitter contact metal 122 may be composed of platinum (Pt).

As depicted in FIG. 2W, the first dummy gate and hardmask region 238 may be removed and subsequently replaced with the gate region 146. Furthermore, both of the layers 202 and 203, as referenced in FIG. 2V, may be removed and replaced with HiKMG gate layers 136 and 137. As illustrated in FIG. 1, base contact 126 and base contact 128 may be formed for electrical connection to the base region 114 via base contact metal 127 and base contact metal 129, respectively. In certain aspects, collector contact 130 and collector contact 132 may be formed for electrical connection to the collector region 110 via collector contact metal 131 and collector contact metal 133, respectively. In certain aspects, emitter contact 120 may be formed for electrical connection to the emitter layer 118 via emitter contact metal 122. Furthermore, dielectric 148 may be disposed adjacent to exposed portions of the dielectric 124. Additional contacts 150, 152, 154, 156, 158, and 160 may be formed, as illustrated.

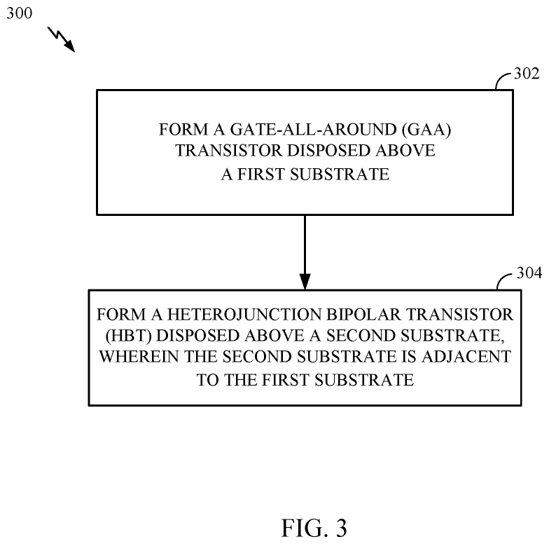

FIG. 3 is a block diagram of operations 300 for fabricating an exemplary semiconductor device (e.g., the semiconductor device 100 depicted in FIG. 1), in accordance with certain aspects of the present disclosure. The operations 300 may be performed by a semiconductor fabrication facility, for example.

The operations 300 begin, at block 302, with the fabrication facility forming a GAA transistor (e.g., the GAA transistor 104) disposed above a first substrate (e.g., the substrate 106). At block 304, the fabrication facility forms an HBT (e.g., the HBT 102) above a second substrate (e.g., the substrate 107), wherein the second substrate is adjacent to the first substrate. In certain aspects, the fabrication facility may form an STI region (e.g., the dielectric region 108) between the first substrate and the second substrate. In certain aspects, the fabrication facility may form the GAA transistor by forming a first channel region (e.g., channel layer 138), forming a second channel region, (e.g., channel layer 139), and forming a first gate region (e.g., the gate layer 136) such that the first gate region is between the first channel and the second channel region. Furthermore, the fabrication facility may form the GAA transistor by forming a second gate region (e.g., the lower gate layer 136) between the first channel region and the first substrate. The fabrication facility may form the semiconductor device such that the first channel region, the second channel region, the first gate region, and the second gate region form a layer stack (e.g., the stack 135 on the GAA transistor 104). Furthermore, the fabrication facility may form the GAA transistor by forming a dielectric layer (e.g., dielectric 124), and forming a third gate region (e.g., gate region 146) such that the dielectric layer is disposed between the third gate region and the layer stack.

In certain aspects, the HBT is a SiGe HBT. Additionally, operations 300 may further include forming an STI region (e.g., dielectric region 108) between the first substrate and the second substrate.

In some cases, forming the GAA transistor may further include forming a material layer (e.g., layer 202 in FIG. 2), and forming the first gate region comprises replacing a portion of the material layer with the first gate region. In certain aspects, another portion of the material layer may include a base region of the HBT. In certain aspects, operations 300 may further include forming the GAA transistor and the HBT by forming another material layer (e.g., channel layer 138 in FIG. 2), wherein forming a second gate region (e.g., lower gate layer 136) of the GAA transistor comprises replacing a portion of the other material layer with the second gate region and removing another portion of the other material layer (see FIG. 2S) prior to forming an emitter region (e.g., emitter layer 118) of the HBT.

In certain aspects, forming the HBT may further comprise forming a collector region (e.g., collector region 110), forming a base region (e.g., base region 114), and forming an emitter region (e.g., emitter layer 118), wherein the collector region, the base region, and the emitter region are formed such that the base region is between the collector region and the emitter region.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. A semiconductor device comprising:
a first substrate;
a second substrate adjacent to the first substrate;
a gate-all-around (GAA) transistor disposed above the first substrate; and
a heterojunction bipolar transistor (HBT) disposed above the second substrate.

2. The semiconductor device of claim 1, wherein the HBT comprises a silicon germanium (SiGe) HBT.

3. The semiconductor device of claim 1, wherein a base region of the HBT comprises p-type SiGe material.

4. The semiconductor device of claim 1, wherein a base region of the HBT comprises SiGe doped with carbon (SiGe:C).

5. The semiconductor device of claim 1, further comprising a shallow trench isolation (STI) region between the first substrate and the second substrate.

6. The semiconductor device of claim 1, wherein the GAA transistor comprises:
a first channel region;
a second channel region; and
a first gate region disposed between the first channel region and the second channel region.

7. The semiconductor device of claim 6, wherein the GAA transistor further comprises a second gate region disposed between the first channel region and the first substrate.

8. The semiconductor device of claim 7, wherein the first channel region, the second channel region, the first gate region, and the second gate region form a layer stack, wherein the GAA transistor further comprises:
a third gate region; and
a dielectric layer disposed between the third gate region and the layer stack.

9. The semiconductor device of claim 1, wherein the HBT comprises:
a collector region;
a base region; and
an emitter region, wherein the base region is disposed between the collector region and the emitter region.

10. The semiconductor device of claim 9, wherein the base region comprises a first material region and a second material region, wherein the first material region has a higher doping concentration than the second material region.

11. The semiconductor device of claim 10, wherein the HBT further comprises a base contact coupled to the first material region.

12. The semiconductor device of claim 9, wherein the collector region comprises a first collector layer and a second collector layer, the first collector layer having a higher doping concentration than the second collector layer.

13. The semiconductor device of claim 12, wherein the HBT further comprises a collector contact coupled to the first collector layer.

14. A method for fabricating a semiconductor device, comprising:
forming a gate-all-around (GAA) transistor above a first substrate; and
forming a heterojunction bipolar transistor (HBT) above a second substrate, wherein the second substrate is adjacent to the first substrate.

15. The method of claim 14, wherein the HBT comprises a silicon germanium (SiGe) HBT.

16. The method of claim 14, further comprising forming a shallow trench isolation (STI) region between the first substrate and the second substrate.

17. The method of claim 14, wherein forming the GAA transistor comprises:
forming a first channel region;
forming a second channel region; and
forming a first gate region such that the first gate region is between the first channel region and the second channel region.

18. The method of claim 17, wherein:
forming the GAA transistor comprises forming a material layer;
forming the first gate region comprises replacing a portion of the material layer with the first gate region; and
another portion of the material layer comprises a base region of the HBT.

19. The method of claim 18, wherein forming the GAA transistor further comprises forming a second gate region of the GAA, and wherein forming the GAA transistor and the HBT comprises:
forming another material layer, wherein forming the second gate region of the GAA transistor comprises replacing a portion of the other material layer with the second gate region; and
removing another portion of the other material layer prior to forming an emitter region of the HBT.

20. The method of claim 17, wherein forming the GAA transistor further comprises forming a second gate region between the first channel region and the first substrate.
